(19) United States
(12) Patent Application Publication
(10) Pub. No.: US 2026/0221093 A1
(43) Pub. Date: Jul. 30, 2026

(54) DISPLAY DEVICE, METHOD OF DRIVING DISPLAY DEVICE, AND ELECTRONIC APPARATUS

(71) Applicant: SONY SEMICONDUCTOR SOLUTIONS CORPORATION, KANAGAWA (JP)

(72) Inventors: RYO TAKAHASHI, KANAGAWA (JP); TAKUMA FUJII, KANAGAWA (JP)

(21) Appl. No.: 19/157,380

(22) PCT Filed: Mar. 26, 2024
(86) PCT No.: PCT/JP2024/011834

§ 371 Date: Aug. 18, 2025

(30) Foreign Application Priority Data
Mar. 30, 2023 (JP) 2023-055485

(51) Int. Cl. G09G 3/3233; G09G 3/20; G09G 3/32

(52) U.S. Cl. CPC G09G 3/3233; G09G 3/2022; G09G 3/32; G09G 2300/0819; G09G 2310/08; G09G 2320/0247; G09G 2320/0276; G09G 2320/045

(57) ABSTRACT

Provided are a display device, a method of driving the display device, and an electronic apparatus capable of preventing occurrence of flicker. The display device includes: a pixel region in which a plurality of pixels is disposed; and a light emission control unit that controls light emission/non-light emission of the pixel, and a length of a light emission period of the pixel in a plurality of divided periods into which one frame of a video to be displayed is divided is adjusted by controlling the light emission and the non-light emission of the pixel.

### TECHNICAL FIELD

The present technology relates to a display device, a method of driving the display device, and an electronic apparatus.

### BACKGROUND ART

In recent years, in the field of display devices, display devices using a current-driven light emitting element in which luminance changes according to a current flowing through a light emitting unit have been widely used. As such a light emitting element, there is an organic light emitting diode (OLED) which is referred to an organic electro luminescent (EL) element, a light emitting polymer element, or the like.

A display device using such an OLED has a problem that flicker occurs in a case where a video to be displayed has a low frame rate. The flicker refers to a fine flicker phenomenon that occurs in display on a display device. Therefore, a technology has been proposed in which a light emission period is divided at a low frame rate, and a non-light emission period is reduced in accordance with a leakage characteristic, so that the luminance is aligned to prevent the occurrence of flicker (Patent Document 1).

### CITATION LIST

### Patent Document

Patent Document 1: Japanese Patent Application Laid-Open No. 2017-227781

### SUMMARY OF THE INVENTION

### Problems to be Solved by the Invention

The technology of Patent Document 1 exhibits an effect of suppressing the flicker, but further improvement of the effect of suppressing the flicker is required.

The present technology has been made in view of such a problem, and an object thereof is to provide a display device, a method of driving the display device, and an electronic apparatus capable of preventing occurrence of flicker.

### Solutions to Problems

In order to solve the above-described problem, a first technology is a display device including: a pixel region in which a plurality of pixels is disposed; and a light emission control unit that controls light emission/non-light emission of the pixel, in which a length of a light emission period of the pixel in a plurality of divided periods into which one frame of a video to be displayed is divided is adjusted by controlling the light emission and the non-light emission of the pixel.

Furthermore, a second technology is a method of driving a display device, which includes a pixel region in which a plurality of pixels is disposed, and a light emission control unit that controls light emission/non-light emission of the pixel, the method including adjusting a length of a light emission period of the pixel in a plurality of divided periods into which one frame of a video to be displayed is divided, by controlling the light emission and the non-light emission of the pixel.

Moreover, a third technology is an electronic apparatus including a display device which includes a pixel region in which a plurality of pixels is disposed, and a light emission control unit that controls light emission/non-light emission of the pixel and in which a length of a light emission period of the pixel in a plurality of divided periods into which one frame of a video to be displayed is divided is adjusted by controlling the light emission and the non-light emission of the pixel.

### BRIEF DESCRIPTION OF DRAWINGS

FIG. 1 is a diagram illustrating a schematic configuration example of a general display device 10.

FIG. 2 is a diagram illustrating a configuration example and an operation of a pixel circuit included in the general display device 10.

FIG. 3 is a diagram illustrating a configuration example and an operation of the pixel circuit included in the general display device 10.

FIG. 4 is a diagram illustrating an example of a timing chart in the pixel circuit of the general display device 10.

FIG. 5 is an explanatory diagram of a problem to be considered in a first embodiment.

FIG. 6 is a pixel circuit diagram for explaining the problem to be considered in the first embodiment.

FIG. 7 is an explanatory diagram of a problem to be considered in the first embodiment.

FIG. 8 is an explanatory diagram of a problem to be considered in the first embodiment.

FIG. 9 is a diagram illustrating a configuration of a display system 100 of the first embodiment.

FIG. 10 is a control sequence diagram in the display system 100.

FIG. 11 is a control sequence diagram in the display system 100.

FIG. 12 is a diagram illustrating a first example of a light emission period and a change in luminance according to the first embodiment.

FIG. 13 is a diagram illustrating a second example of the light emission period and the change in luminance according to the first embodiment.

FIG. 14 is an explanatory diagram of a problem to be considered in a second embodiment.

FIG. 15 is a diagram illustrating a light emission period and a change in luminance according to the second embodiment.

FIG. 16 is an explanatory diagram of a problem to be considered in a third embodiment.

FIG. 17 is a diagram illustrating a light emission period and a change in luminance in the third embodiment.

FIG. 18 is a perspective view illustrating an example of an appearance of a head-mounted display.

FIG. 19 is a perspective view illustrating an example of an appearance of a see-through head-mounted display.

FIG. 20A is a front view illustrating an example of an appearance of a digital still camera. FIG. 20B is a rear view illustrating an example of an appearance of the digital still camera.

FIG. 21 is a perspective view illustrating an example of an appearance of a television apparatus.

FIG. 22 is a perspective view illustrating an example of an appearance of a smartphone.

FIG. 23A is a diagram illustrating an example of an internal state of a vehicle from a rear side to a front side of the vehicle. FIG. 23B is a diagram illustrating the example of the internal state of the vehicle from an oblique rear to an oblique front of the vehicle.

### MODE FOR CARRYING OUT THE INVENTION

Embodiments and the like of the present technology are described below, with reference to the drawings. The description will be given in the following order. Note that, in the present specification and the drawings, components having substantially the same function or configuration are denoted by the same reference numerals, and redundant explanations are omitted appropriately.

### <Configuration Example of General Display Device>

### [Configuration Example of Pixel Circuit]

### First Embodiment

### [Problems to be Considered in First Embodiment]

### [Configuration and Driving Method of Display Device]

### Second Embodiment

### [Problems to be Considered in Second Eembodiment]

### [Configuration and Driving Method of Display Device]

### Third Embodiment

### [Problems to be Considered in Third Eembodiment]

### [Configuration and Driving Method of Display Device]

### Application Example

### <Modification>

### <Configuration Example of General Display Device>

First, in order to facilitate understanding of the present technology, a configuration example and an operation example of a general display device 10 will be described.

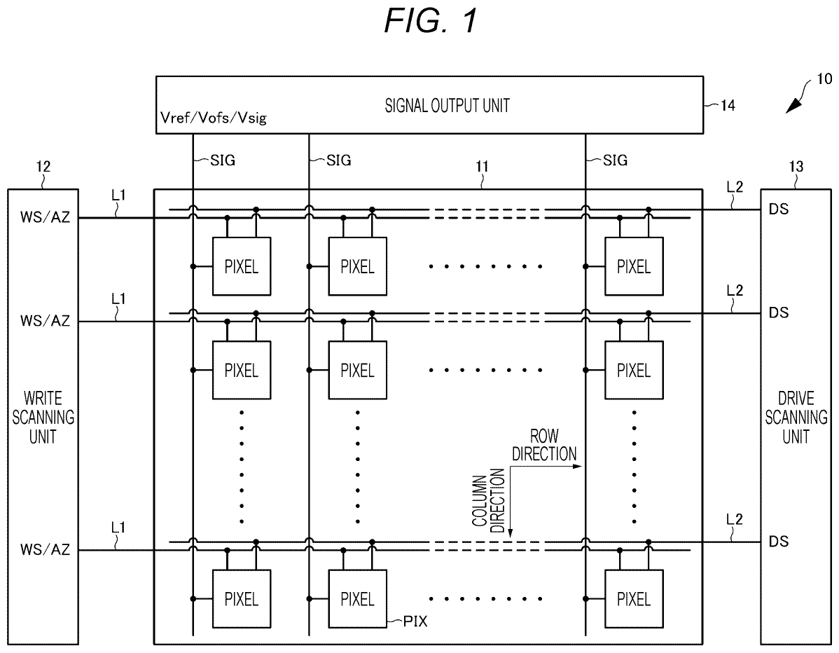

FIG. 1 illustrates a schematic configuration example of the general display device 10. The display device 10 is, for example, an organic electro luminescence (EL) display device including an active matrix type drive circuit and using an OLED as a light emitting element. Note that the display device 10 may use another light emitting element such as a micro light emitting diode (LED) or a quantum dot light emitting element.

The display device 10 includes a pixel array unit 11 which is provided on a display panel and in which a plurality of pixels PIX including organic EL elements is two-dimensionally disposed in a matrix. Furthermore, the display device 10 includes a write scanning unit 12, a drive scanning unit 13, and a signal output unit 14 which are mounted on the same display panel as the pixel array unit 11 and are disposed around the pixel array unit 11.

The pixel array unit 11 is a pixel region in which a plurality of pixels PIX is two-dimensionally disposed in a matrix. In the pixel array unit 11, a plurality of scanning lines L1 and a plurality of drive lines L2 are wired for each pixel PIX row along a row direction (an array direction of the pixels of the pixel row) with respect to the array of the pixels PIX in a matrix shape. Furthermore, a plurality of signal lines SIG is wired for each pixel column along a column direction (an array direction of the pixels of the pixel column) with respect to the arrangement of the pixels PIX in the matrix shape. The pixel PIX includes a light emitting element OLED, which is an example of a light emitting element, and a pixel circuit.

The scanning line L1 is connected to an output end of a corresponding row of the write scanning unit 12. The drive line L2 is connected to an output end of a corresponding row of the drive scanning unit 13. The signal line SIG is connected to an output end of a corresponding column of the signal output unit 14.

The pixel array unit 11 is provided with pixels PIX (also referred to as sub-pixels) corresponding to pixels of three primary colors of red (R), green (G), and blue (B). These three pixels express one dot of a color image. Note that a combination of pixels expressing one dot is not limited to this, and a W (white) pixel for improving luminance may be added, or a complementary pixel for expanding a color reproduction range may be added. Furthermore, the pixel PIX is not limited to the color image, and may be configured to express a monochrome (black-and-white) image.

In the display device 10, N number of pixels PIX arranged in an m-th row are simultaneously driven. In other words, for N number of pixels PIX arranged along the row direction, a timing of light emission/non-light emission of light is controlled in units of row to which the pixels PIX belong. Given that a display frame rate of the display device 10 is represented as FR (times/second), a scan period per row (so-called horizontal scan period) when the display device 10 is line-sequentially scanned in units of row is shorter than (1/FR)×(1/M) seconds.

The write scanning unit 12 includes a write scanner (Write Scan) and an auto zero scanner (Auto Zero Scan). When a signal voltage of a video signal is written to each pixel PIX of the pixel array unit 11, the write scanning unit 12 sequentially supplies a write scanning signal (signal WS) and a control signal (signal AZ) to the scanning line L1 to scan each pixel PIX of the pixel array unit 11 in order in units of row. The write scanning unit 12 includes a shift register circuit and the like.

The write scanner controls writing of the video signal (signal voltage) to each pixel PIX. For example, when writing the video signal to each pixel PIX of the pixel array unit 11, the write scanner sequentially supplies the signal WS to each scanning line L1 to scan (line sequential scanning) each pixel PIX of the pixel array unit 11 in order in units of row.

The auto zero scanner controls initialization of each pixel PIX. Specifically, the auto zero scanner supplies the signal AZ to the scanning line L1 in synchronization with the scanning of the write scanner, so that control is performed to prevent the pixel PIX from emitting light during an extinction period.

The drive scanning unit 13 corresponds to a light emission control unit in the claims, and includes a drive scanner (Drive Scan). The drive scanner supplies a light emission control signal (signal DS) to the drive line L2 in synchronization with the line sequential scanning by the write scanning unit 12, thereby controlling light emission/non-light emission (extinction) of the pixel PIX. The drive scanning unit 13 includes a shift register circuit and the like.

The signal output unit 14 outputs a video signal supplied from a control circuit (not illustrated) or the like to each signal line SIG. The signal output unit 14 selectively outputs a reference voltage Vref, various reference voltages (for example, a reference voltage Vofs used when a correction operation for correcting a threshold voltage of a DR transistor to be described later is performed) serving as a reference of a signal voltage Vsig, and the signal voltage Vsig corresponding to the video signal.

The reference voltage Vref/reference voltage Vofs/the signal voltage Vsig selectively output from the signal output unit 14 is written to each pixel PIX of the pixel array unit 11 via the signal line SIG in units of pixel rows selected by the line sequential scanning by the write scanning unit 12.

### [Configuration Example of Pixel Circuit]

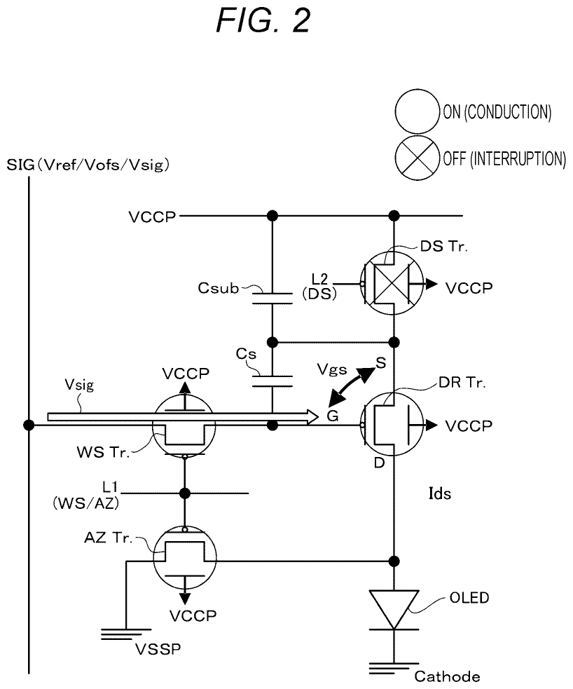

Next, a configuration example and an operation of the pixel circuit included in the pixel PIX will be described with reference to FIGS. 2 to 4. The pixel circuit which drives the light emitting element OLED includes a WS transistor, a DS transistor, a DR transistor, an AZ transistor, a holding capacitor Cs, an auxiliary capacitor Csub, and the light emitting element OLED. That is, the pixel circuit in this example is a pixel circuit having a 4-Transistor (Tr) 2-Capacitor (C) configuration.

The WS transistor, the DS transistor, the DR transistor, and the AZ transistor are, for example, P-type metal oxide semiconductor field effect transistors (MOSFET). Each transistor is a transistor having four terminals of a source, a gate, a drain, and a back gate, and the back gate of each transistor is connected to a power supply line VCCP.

In the WS transistor, the gate is connected to the scanning line L1, the source is connected to the signal line SIG, and the drain is connected to the gate of the DR transistor and the holding capacitor Cs. In the auxiliary capacitor Csub, one end is connected to the power supply line VCCP, and the other end is connected to the holding capacitor Cs, the drain of the DS transistor, and the source of the DR transistor. In the holding capacitor Cs, one end is connected to the other end of the auxiliary capacitor Csub, the drain of the DS transistor, and the source of the DR transistor, and the other end is connected to the drain of the WS transistor and the gate of the DR

In the DS transistor, the gate is connected to the drive line L2, the source is connected to the power supply line VCCP, and the drain is connected to the source of the DR transistor, the other end of the auxiliary capacitor Csub, and one end of the holding capacitor Cs. In the DR transistor, the gate is connected to the drain of the WS transistor and the other end of the holding capacitor Cs, the source is connected to the drain of the DS transistor, the other end of the auxiliary capacitor Csub, and one end of the holding capacitor Cs, and the drain is connected to the anode of the light emitting element OLED and the source of the AZ transistor.

The gate of the AZ transistor is connected to the scanning line L1, the source is connected to the drain of the DR transistor and the anode of the light emitting element OLED, and the drain is connected to the power supply line VSSP.

The light emitting element OLED is an organic EL light emitting element, an anode at one end is connected to the drain of the DR transistor and the source of the AZ transistor, and the other end is a cathode.

With this configuration, in the pixel PIX, when the WS transistor is in the on state, the voltage between both ends of the holding capacitor Cs is set on the basis of the video signal supplied from the signal line SIG. The DS transistor is turned on and off on the basis of the signal of the drive line L2. The DR transistor causes a current corresponding to the voltage between both ends of the holding capacitor Cs to flow through the light emitting element OLED during a period in which the DS transistor is in the on state. The light emitting element OLED emits light on the basis of the current supplied from the DR transistor. In this manner, the pixel PIX emits light with luminance corresponding to the video signal. The AZ transistor is turned on and off on the basis of the signal of the scanning line L1. During the period in which the AZ transistor is in the on state, the voltage of the anode of the light emitting element OLED is initialized by being set to the voltage of the power supply line VSSP.

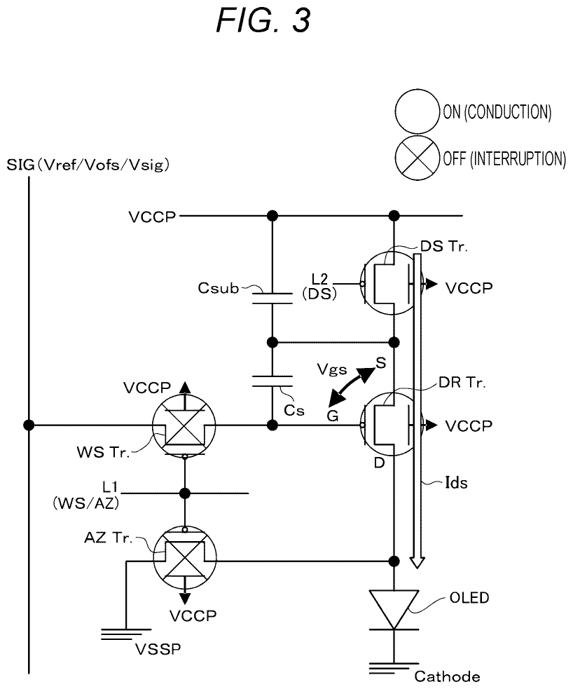

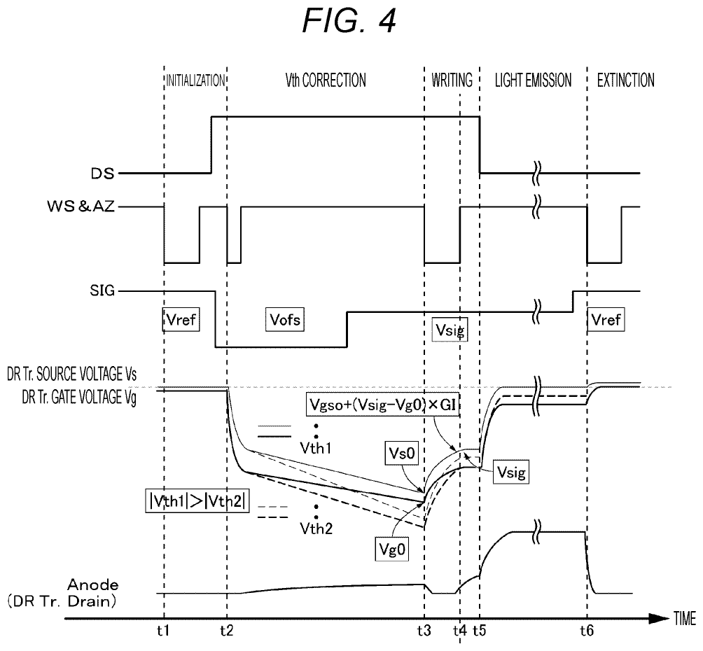

Next, driving of the pixel circuit illustrated in FIGS. 2 and 3 will be described with reference to a timing chart of FIG. 4. The timing chart of FIG. 4 illustrates temporal transitions of the signal WS and the signal AZ supplied to the scanning line L1, the signal DS supplied to the drive line L2, the potential Vref/Vofs/Vsig of the signal line SIG, the source voltage Vs and the gate voltage Vg of the DR transistor, and the anode of the light emitting element OLED (the drain voltage of the DR transistor). Note that in FIG. 4, one horizontal period (1H) includes five periods (initialization, Vth correction, writing, light emission, and extinction).

At time t1, the signal WS and the signal AZ transition from high to low, the light emission period ends, and the initialization period (t1 to t2) starts in which the DR transistor is initialized.

In a period from time t1 to time t2, the signal WS and the signal AZ become high, and the reference voltage Vref decreases to the reference voltage Vofs. Furthermore, the signal DS becomes high in the period from time t1 to time t2. Then, at time t2, the signal WS and the signal AZ become low, and the Vth correction period starts in which the threshold voltage Vth of the DR transistor which may vary in each pixel PIX is corrected.

The Vth correction period is a period for correcting the threshold voltage Vth of the DR transistor which may vary in each pixel PIX. In the Vth correction period, the signal WS is set to low to turn on the WS transistor, and then the signal WS is set to high to turn off the WS transistor. Then, when the signal DS becomes high and the DS transistor is turned off, the source voltage Vs and the gate voltage Vg of the DR transistor decrease. Then, a gate-source voltage Vgs of the DR transistor converges to the threshold voltage Vth of the DR transistor, the gate-source voltage Vgs is set to the threshold voltage Vth of the DR transistor, and the voltage corresponding to the threshold voltage Vth is held in the holding capacitor Cs.

As illustrated in FIG. 2, the next writing period is a period in which the signal voltage Vsig corresponding to the video signal is written to the pixel PIX. Specifically, at time t3, the signal WS transitions from high to low, and the WS transistor transitions from off to on, so that the gate voltage Vg of the DR transistor becomes the signal voltage of the signal line SIG. At this time, the signal voltage Vsig is applied to the signal line SIG, and the gate voltage Vg of the DR transistor becomes the signal voltage Vsig. Furthermore, the holding capacitor Cs holds the signal voltage Vsig written by the WS transistor. Then, at time t4, the signal WS becomes high and the WS transistor is turned off, so that the period of writing the signal voltage Vsig to the DR transistor ends.

Next, at time t5, the signal DS transitions from high to low, and the DS transistor transitions from off to on, thereby shifting to the light emission period. During the light emission period, as illustrated in FIG. 3, the DS transistor is turned on, so that a drain-source current Ids corresponding to the gate-source voltage Vgs held in the holding capacitor Cs flows through the light emitting element OLED, and the light emitting element OLED emits light.

Then, the signal WS and the signal AZ become low at time t6, thereby ending the light emission ends and shifting to the extinction period (t5 to the next initialization start time). This series of operations are executed, for example, in one horizontal period.

When the DS transistor is turned off, no current is supplied from the DR transistor to the light emitting element OLED, and the light emitting element OLED enters a non-light emitting state. That is, the period in which the DS transistor is off is the non-light emission period of the light emitting element OLED.

### First Embodiment

### [Problems to be Considered in First Embodiment]

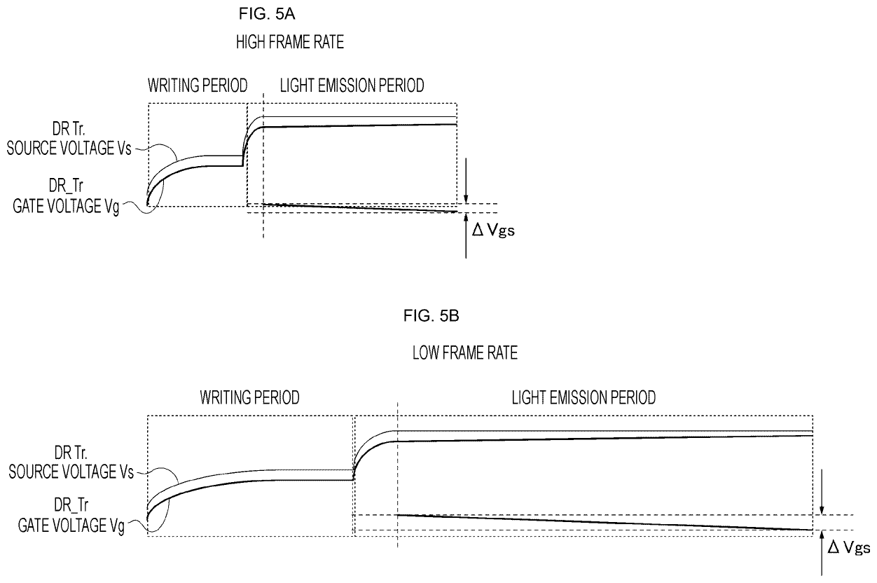

Next, a decrease in luminance at the time of light emission of the pixel PIX, which is a problem to be considered in the first embodiment, will be described. FIG. 5A illustrates the writing period and the light emission period of the timing chart extracted in a case where a video displayed by the display device 10 has a high frame rate. Furthermore, FIG. 5B illustrates the writing period and the light emission period of the timing chart extracted in a case where the video displayed by the display device 10 has a low frame rate. In the present technology, the high frame rate is a frame rate of 30 Hz or more, and the low frame rate is a frame rate of less than 30 Hz. However, the present technology is not limited to this value.

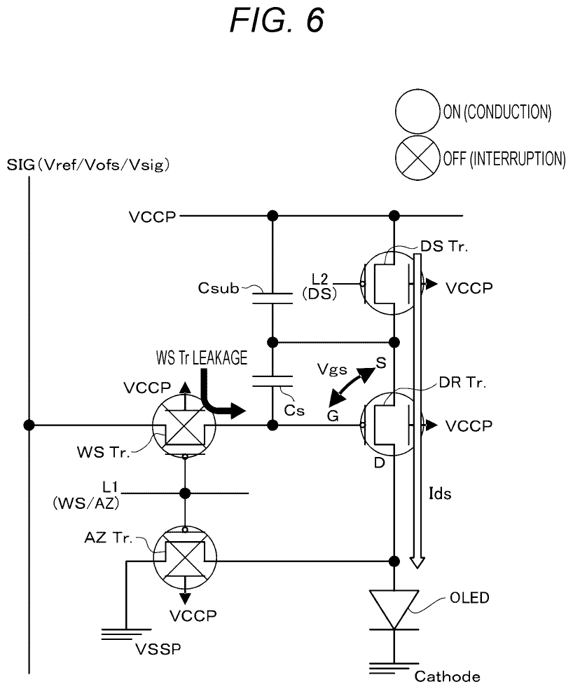

In the case of the low frame rate, the light emission period is longer than that in the case of the high frame rate as illustrated in FIG. 5B, and thus, in the light emission period, the period in which the gate voltage Vg of the DR transistor rises is also longer than that in the case of the high frame rate, and an amount of rise in the gate voltage Vg increases. Furthermore, at the low frame rate, as illustrated in FIG. 6, the amount of rise in the gate voltage Vg of the DR transistor increases due to leakage of the WS transistor. As a result, the gate-source voltage Vgs of the DR transistor decreases, and the drain-source current Ids decreases due to the decrease, whereby the luminance of the light emitting element OLED decreases, and the luminance of the pixel PIX decreases.

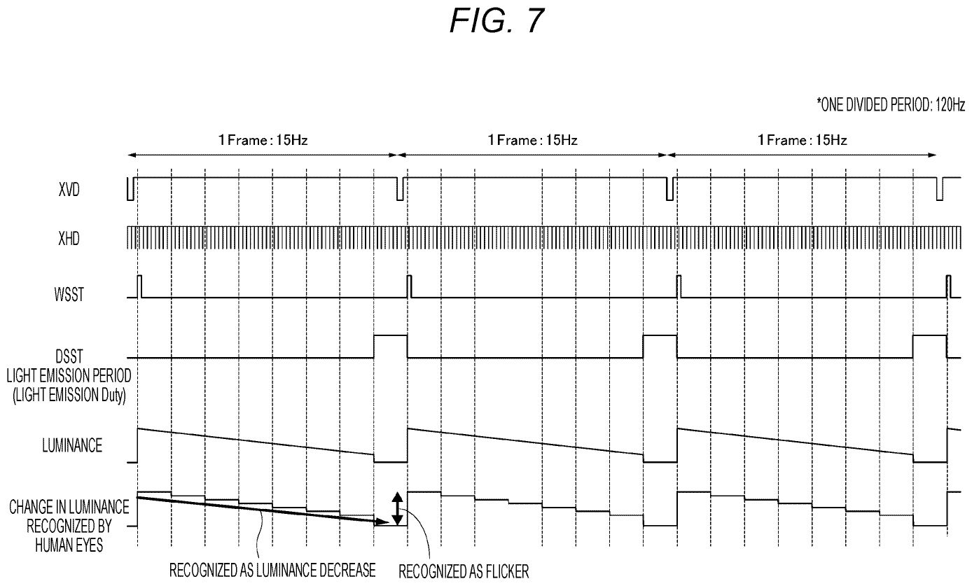

FIG. 7 illustrates a vertical synchronization signal XVD, a horizontal synchronization signal XHD, a signal WSST, a signal DSST, and a change in the luminance of the pixel PIX for each frame of the video in a normal video display in the display device 10. In a case where the entire period of one frame (15 Hz) (one vertical scanning period) is set as the light emission period of the pixel PIX, a current gradually leaks from the holding capacitor Cs within the period of one frame, and the potential of the holding capacitor Cs decreases. Thus, in a case where the light emission period (light emission duty) of the pixel PIX for each frame is uniform, the luminance of the pixel PIX decreases every frame. Then, a luminance difference between the last luminance of the frame and the initial luminance of the next frame is recognized as flicker by a viewer of the video on the display device 10.

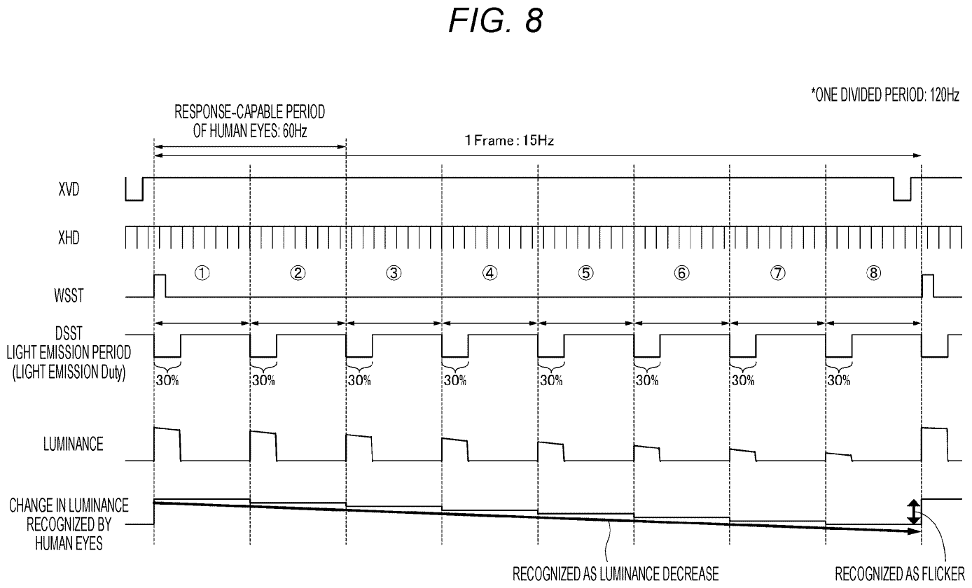

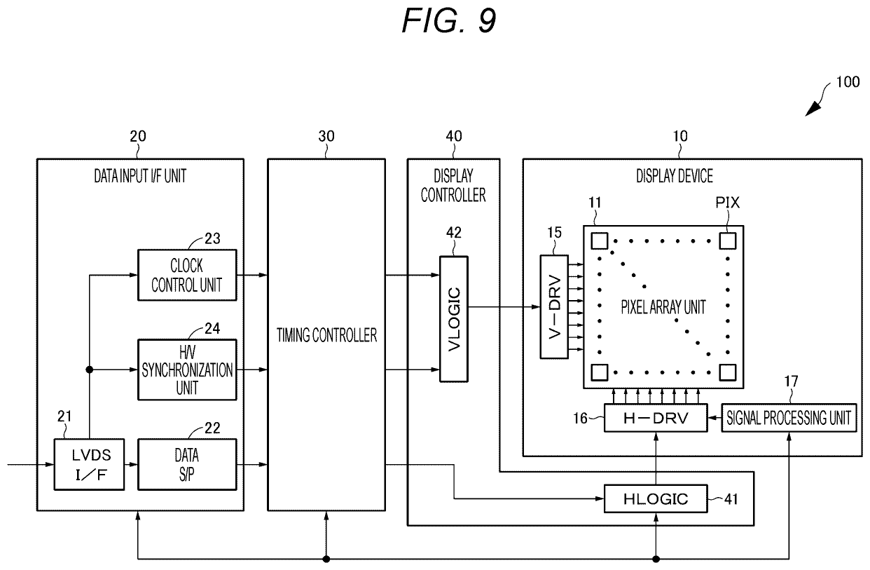

In this regard, as illustrated in FIG. 8, there is a method of dividing the light emission period (light emission duty) of the pixel PIX. In the example of FIG. 8, one frame (15 Hz) of the video displayed by the display device 10 is divided into eight divided periods. One divided period is 120 Hz. Then, the light emission period of the pixel PIX in each divided period is uniformly shortened. In FIGS. 8, 30% is set as an example. A ratio of the light emission period is a ratio in a case where the length of the light emission period in the last divided period (an eighth divided period in FIG. 9) in one frame is 100%.

Therefore, it is possible to prevent the flicker occurring at 60 Hz driving as compared with the case of FIG. 7. However, the luminance of the pixel PIX decreases every frame due to the decrease in the potential of the holding capacitor Cs during the low frame rate operation. Then, similarly to the case of FIG. 7, the luminance difference between the luminance in the last divided period of the frame and the luminance in the first divided period which is the initial divided period of the next frame is recognized as flicker by the viewer of the video on the display device 10.

### [Configuration and Driving Method of Display Device]

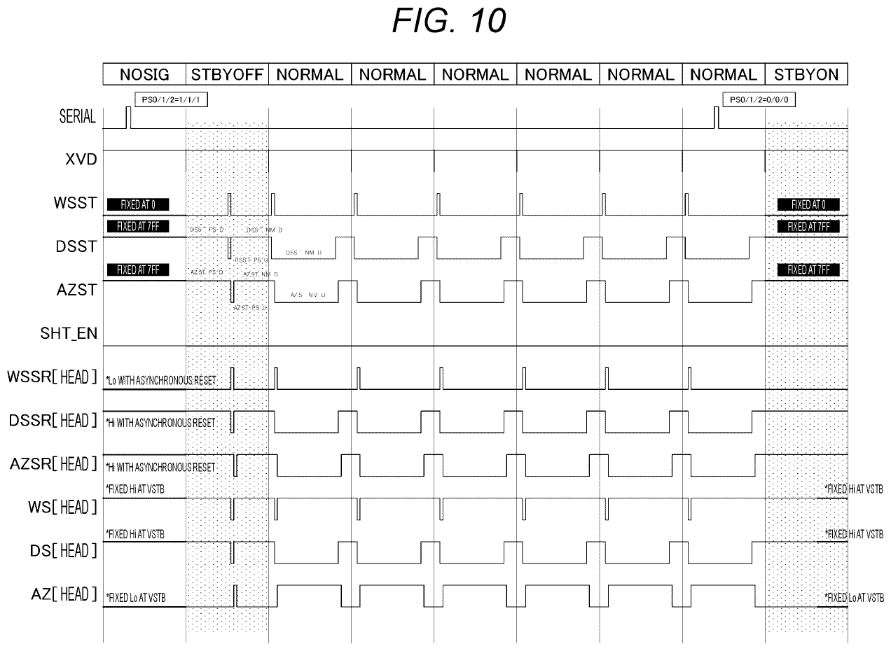

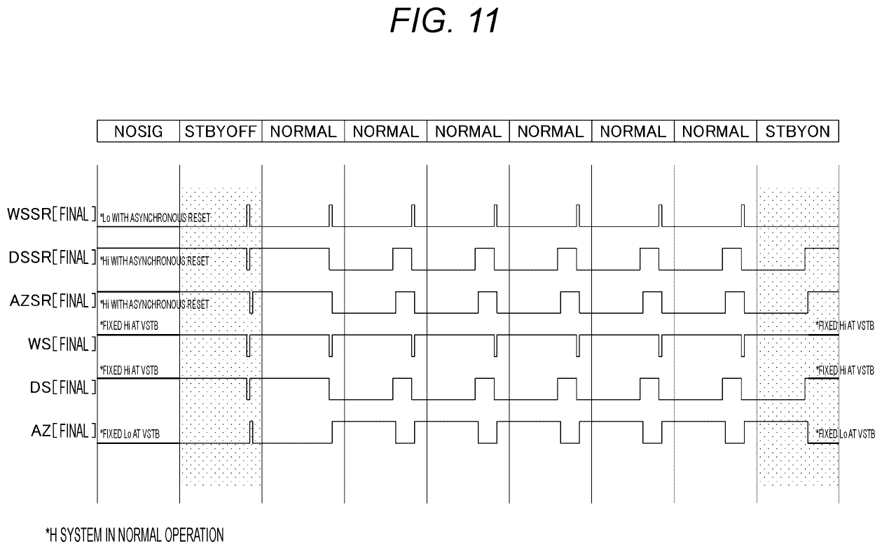

Next, a configuration and a driving method of the display device 10 according to the first embodiment will be described with reference to FIGS. 9 to 11. Note that the same components as those of the general display device 10 described with reference to FIG. 1 are denoted by the same reference numerals, and description thereof is omitted.

The display system 100 includes the display device 10, a data input I/F unit 20, a timing controller 30, and a display controller 40.

The display device 10 includes the pixel array unit 11, a V-DRV 15, an H-DRV 16, and a signal processing unit 17.

The pixel array unit 11 includes a plurality of pixel circuits disposed in a horizontal direction and a vertical direction. The configurations of the pixel array unit 11 and the pixel circuit are similar to those described with reference to FIGS. 1 and 2.

The V-DRV 15 includes the write scanning unit 12 and the drive scanning unit 13. As described above, when the signal voltage of the video signal is written to each pixel PIX of the pixel array unit 11, the write scanning unit 12 sequentially supplies the signal WS and the signal AZ to the scanning line L1 to scan each pixel PIX of the pixel array unit 11 in order in units of rows.

As described above, the drive scanning unit 13 supplies the light emission control signal (signal DS) to each drive line L2 in synchronization with the line sequential scanning by the write scanning unit 12, thereby controlling the light emission/non-light emission (extinction) of the pixel PIX.

The H-DRV 16 includes the signal output unit 14. As described above, the signal output unit 14 selectively outputs the reference voltage Vref, the signal voltage Vsig, and the reference voltage Vofs, and the output voltages are supplied to each pixel PIX via the signal line SIG and written in units of pixel rows selected by scanning by the write scanning unit 12.

The signal processing unit 17 performs signal processing of a video signal to be displayed on the pixel array unit 11. The signal processing unit 17 performs gamma correction on the basis of a luminance adjustment signal from the timing controller 30.

The video signal processed by the signal processing unit 17 is supplied to the H-DRV 16.

The data input I/F unit 20 includes a low voltage differential signaling (LVDS) I/F 21, data S/P 22, a clock control unit 23, and an H/V synchronization unit 24. The LVDS I/F 21 unit receives a video signal from an outside. The data S/P 22 converts the video signal into parallel data, and then supplies the parallel data to an image processing unit 33 of the timing controller 30. The clock control unit 23 generates a clock that suits display frequency of the display device 10. The H/V synchronization unit 24 generates a signal that defines a horizontal synchronization timing and a vertical synchronization timing of the display device 10, and supplies the signal to the timing generator 32.

The timing controller 30 has a clock generation function and a timing generation function, generates a vertical synchronization clock and a horizontal synchronization clock of the display device 10, and supplies the generated clocks to a VLOGIC 42 of the display controller 40. Furthermore, the timing controller 30 generates a signal that defines an operation timing of the display controller 40 and supplies the signal to the VLOGIC 42 of the display controller 40. Specifically, the timing controller 30 supplies, to the VLOGIC 42, the signal WSST1 defining a write head position, a signal DSST defining the light emission period in a L period, and a signal AZST defining the extinction period in the L period. By changing an internal setting (register), the timing controller 30 generates the signal DSST defining the light emission period according to the present technology to be described later. The timing controller 30 adjusts the light emission period of the pixel PIX in the present technology.

The timing controller 30 further has an image processing function, and performs predetermined signal processing on the video signal input from the data S/P 22. The processed video signal is supplied to an HLOGIC 41 of the display controller 40.

The display controller 40 includes the HLOGIC 41 and the VLOGIC 42, and performs display control on the pixel array unit 11. The HLOGIC 41 supplies the video signal to the H-DRV 16.

The VLOGIC 42 generates a signal defining the timings of the scanning line L1 and the drive line L2, on the basis of the signal input from the timing controller 30, and supplies the signal to the V-DRV 15. Specifically, the VLOGIC 42 supplies, to the V-DRV 15, a signal WSSR for controlling the write timing of each line in a H period, a signal DSSR for controlling the light emission timing of each line in the L period, and a signal AZSR for controlling the extinction timing of each line in the L period.

The V-DRV 15 supplies, to the pixel circuit, the signal WS for controlling the write timing in the L period, the signal DS for controlling the light emission timing in the L period, and the signal AZ for controlling the extinction timing in the L period on the basis of the signal input from the VLOGIC 42.

An interface 50 connects a data input IF to an external device, a network, or the like, and for example, a mobile industry processor interface (MIPI) or the like can be used.

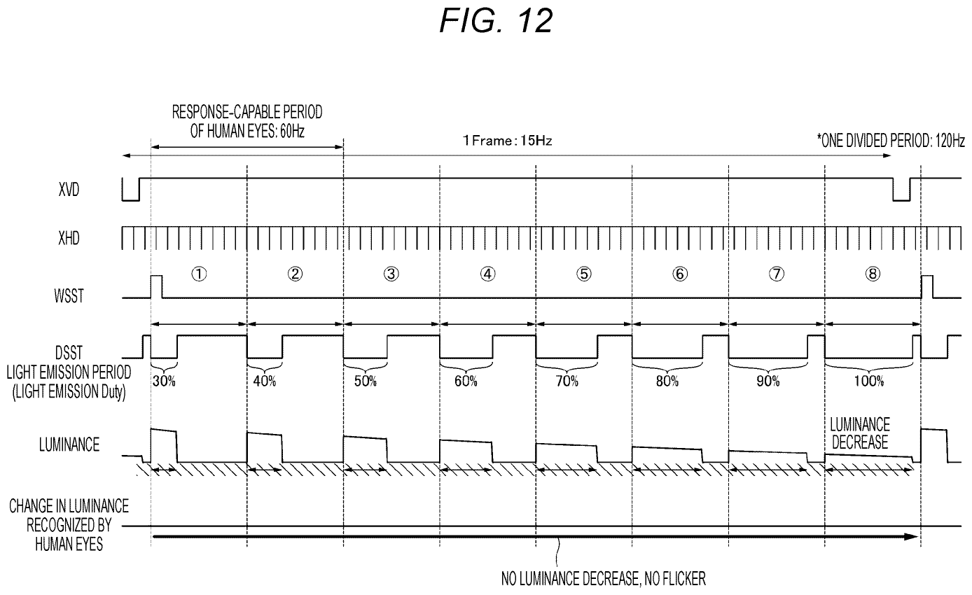

FIG. 12 is a diagram illustrating the vertical synchronization signal XVD, the horizontal synchronization signal XHD, the signal WSST, the signal DSST, and the change in the luminance of the pixel PIX for each frame of the low-frame-rate video displayed on the display device 10 and the adjustment of the light emission period in the first embodiment. As described above, the signal WSST is a signal that defines the write head position, and the signal DSST is a signal that defines the light emission period of the pixel PIX. The low frame rate is assumed to be a frame rate of less than 30 Hz as described above.

The entire period (15 Hz) (one vertical scanning period) of one frame is set as the light emission period of the pixel PIX, and one frame is divided into periods shorter than a response-capable period of human eyes so as to be shorter than the response-capable period of human eyes. In the example of FIG. 12, one frame is divided into eight divided periods, and one divided period is set to 120 Hz. The response-capable period of human eyes is about 60 Hz.

In the first embodiment, a length of time for turning on the signal DSST for each frame, that is, the light emission period of the pixel PIX is lengthened stepwise with the lapse of time.

In the example of FIG. 12, specifically, the light emission period of the first divided period, which is the initial divided period, is set to 30%. The light emission period of a second divided period is set to 40%. The light emission period of a third divided period is set to 50%. The light emission period of a fourth divided period is set to 60%. The light emission period of a fifth divided period is set to 70%. The light emission period of a sixth divided period is set to 80%. The light emission period of a seventh divided period is set to 90%. The light emission period of the eighth divided period, which is the last divided period, is set to 100%. That is, with the lapse of time, the ratio of the light emission Duty in each divided period is increased stepwise from the first divided period to the eighth divided period which is the last divided period, and the light emission period is adjusted so as to be gradually lengthened stepwise.

For example, by changing the setting (register) of the timing controller 30 according to the decrease amount of the pixel PIX specified in advance by measurement, calculation, or the like, the timing controller 30 generates the signal DSST defining the light emission period and supplies the signal DSST to the VLOGIC 42. Then, by supplying the signal DS as the light emission control signal from the V-DRV 15 to the pixel circuit via the VLOGIC 42, the light emission/non-light emission of the light emitting element OLED is controlled to adjust the length of the light emission period of the pixel PIX.

As described with reference to FIGS. 7 and 8, the luminance of the pixel PIX decreases with the lapse of time, and thus adjustment may be performed such that the light emission period of the pixel PIX is lengthened stepwise with the lapse of time.

A ratio of the length of the light emission period in each divided period is a ratio in a case where the length of the light emission period in the last divided period (the eighth divided period in FIG. 12) in one frame is 100%.

As described above, by lengthening the light emission period stepwise as the luminance gradually decreases in one frame, it is possible to prevent the decrease in the luminance of the pixel PIX. Therefore, there is no difference between the luminance in the eighth divided period which is the last divided period of the frame and the luminance in the first divided period which is the initial divided period of the next frame, and the occurrence of flicker can be prevented.

Note that, in FIG. 12, the light emission period of each divided period is changed stepwise every 10%, but this is merely an example, and the light emission period may be changed in any manner as long as the light emission period is lengthened stepwise with the lapse of time and the light emission period in the last divided period becomes 100%.

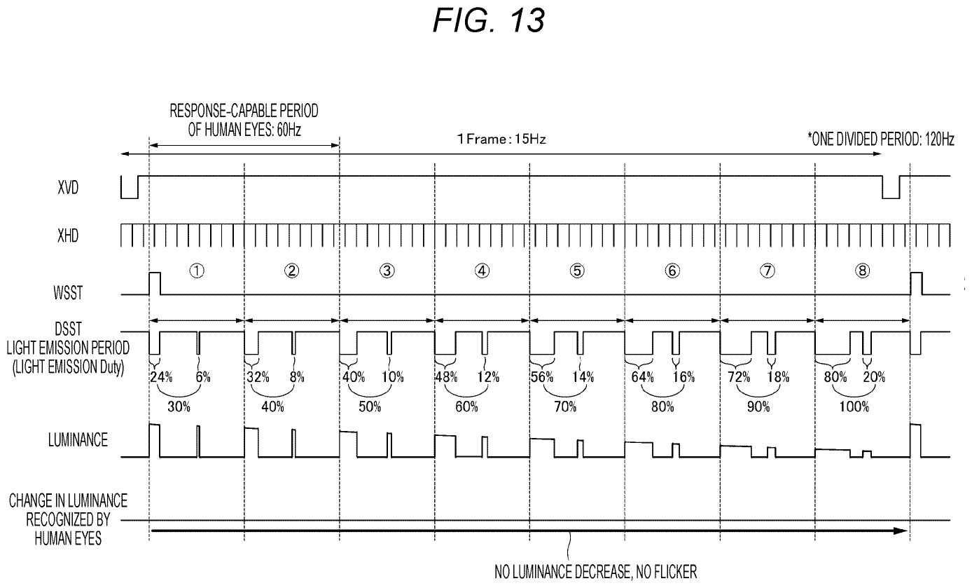

Note that, as illustrated in FIG. 13, one frame may be divided into a plurality of divided periods less than the response-capable period (60 Hz) of human eyes, and the light emission period in each divided period may be further divided.

As a result, similarly to the case of FIG. 12, it is possible to prevent the decrease in the luminance and to prevent the occurrence of flicker.

In the example of FIG. 13, the light emission period of the first divided period in which the light emission period is 30% is divided into 24% and 6%. The light emission period of the second divided period in which the light emission period is 40% is divided into 32% and 8%. The light emission period of the third divided period in which the light emission period is 50% is divided into 40% and 10%. The light emission period of the fourth divided period in which the light emission period is 60% is divided into 48% and 12%. The light emission period of the fifth divided period in which the light emission period is 70% is divided into 56% and 14%. The light emission period of the sixth divided period in which the light emission period is 80% is divided into 64% and 16%. The light emission period of the seventh divided period in which the light emission period is 90% is divided into 72% and 18%. The light emission period of the eighth divided period in which the light emission period is 100% is divided into 80% and 20%.

Note that the division method illustrated in FIG. 13 is merely an example, and the present technology is not limited to the division method. For example, the first divided period in which the light emission period is 30% may be divided into 15% and 15%, or may be divided into 6% and 24%. The method of division is not limited. Furthermore, the light emission period in one divided period may be divided into three or more.

### Second Embodiment

### [Problems to be Considered in Second Embodiment]

Next, a second embodiment of the present technology will be described. The configurations of the display device 10 and the pixel circuit are similar to those of the first embodiment.

In the second embodiment, black floating is prevented. The black floating means that the luminance becomes larger than an ideal characteristic in the light emitting element OLED, so that light leakage partially occurs at the time of black display. Therefore, black becomes lighter in the pixel PIX, and deterioration of contrast or the like occurs.

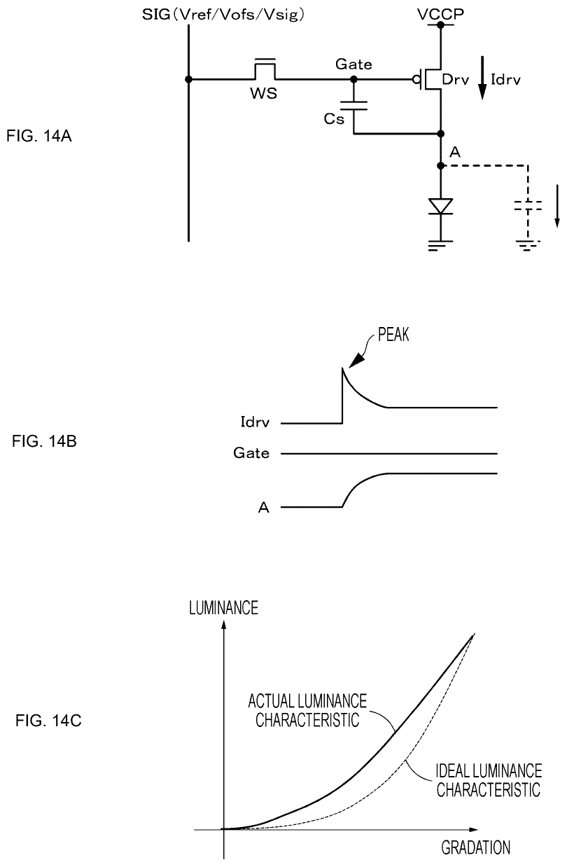

In a case where the pixel circuit uses a source follower drive, the gate-source voltage Vgs of the DR transistor increases, so that a drive current Idrv increases. Then, as the increased drive current Idrv flows, an output voltage at the anode (the drain voltage of the DR transistor) of the light emitting element OLED illustrated at a node A in FIG. 14A rises.

In the case of the source follower drive, as illustrated in FIG. 14B, a peak of the current value occurs at the beginning of the flow of the drive current Idrv, and the amount of the drive current Idrv flowing through the light emitting element OLED increases at the start of the light emission of the light emitting element OLED. Therefore, as illustrated in FIG. 14C, the light emission amount of the light emitting element OLED increases, and in the actual luminance characteristic of the light emitting element OLED, the luminance becomes higher than the ideal luminance characteristic, so that the black floating occurs.

### [Configuration and Driving Method of Display Device]

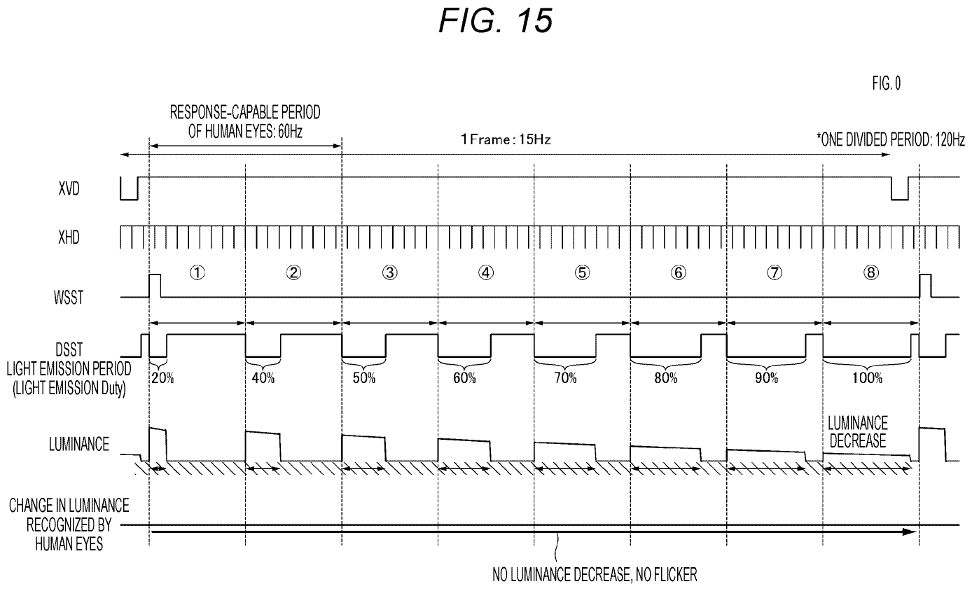

A configuration and a driving method of the display device 10 according to the second embodiment will be described. The configurations of the display system 100 and the display device 10 in the second embodiment are similar to those in the first embodiment. FIG. 15 is a diagram illustrating the vertical synchronization signal XVD, the horizontal synchronization signal XHD, the signal WSST, the signal DSST, and the change in the luminance of the pixel PIX for each frame of the video displayed on the display device 10 and the adjustment of the light emission period according to the second embodiment.

In the second embodiment, as illustrated in FIG. 15, in order to suppress the occurrence of flicker and prevent the occurrence of black floating, the period of one frame (for example, 15 Hz) (one vertical scanning period) is divided into periods less than the response-capable period of human eyes, similarly to the first embodiment.

Then, the light emission period of the pixel PIX in the divided period corresponding to the period in which the peak of the drive current Idrv occurs is shortened. Therefore, the amount of light emission in the divided period corresponding to the period in which the peak of the drive current Idrv occurs can be suppressed to prevent the occurrence of black floating due to the peak at the beginning of the flow of the drive current Idrv.

In the example of FIG. 15, specifically, as the divided period corresponding to the period in which the peak of the drive current Idrv occurs, the light emission period of the first divided period is set to 20%, which is shorter than that of the first embodiment.

After the drive current Idrv is stabilized, similarly to the first embodiment, the light emission duty is increased stepwise with the lapse of time, and the light emission period is adjusted to be lengthened stepwise. Thus, the light emission period of the second divided period is set to 40%. The light emission period of a third divided period is set to 50%. The light emission period of a fourth divided period is set to 60%. The light emission period of a fifth divided period is set to 70%. The light emission period of a sixth divided period is set to 80%. The light emission period of a seventh divided period is set to 90%. The light emission period of the eighth divided period is set to 100%.

For example, by changing the setting (register) of the timing controller 30 according to the peak of the drive current Idrv specified in advance by measurement, calculation, or the like, the timing controller 30 generates the signal DSST for controlling the light emission period as described above, and supplies the signal DSST to the VLOGIC 42. Then, by supplying the signal DS from the V-DRV 15 to the pixel circuit, the light emission/non-light emission of the light emitting element OLED is controlled to adjust the light emission period of the pixel PIX.

In FIG. 15, the Light Emission Period of the Pixel Pix in the first divided period is set to 20%, but this is merely an example, and the duration of the light emission period in the divided period corresponding to the period in which the peak of the drive current Idrv occurs may be appropriately set according to the peak of the drive current Idrv.

Note that, in FIG. 15, only the light emission period in the first divided period is shortened in order to prevent the black floating, but in order to prevent the black floating, it is necessary to shorten the light emission period of the pixel PIX in the divided period corresponding to the period in which the peak of the drive current Idrv occurs. Thus, for example, in a case where the period in which the peak of the drive current Idrv occurs is the first divided period and the second divided period, it is necessary to shorten the light emission periods in the two divided periods.

As described above, in the second embodiment, the light emission period of each divided period is adjusted to be lengthened stepwise from the first divided period to the last divided period among the plurality of divided periods, and the amount of change in the length of the light emission period from the first divided period to the second divided period is adjusted to be larger than the amount of change in the length of the light emission period from the second divided period to the third divided period.

### Third Embodiment

### <Problems to be Considered in Third Embodiment>

Next, a third embodiment of the present technology is described. The configurations of the display device 10 and the pixel circuit are similar to those of the first embodiment.

In the third embodiment, black level depression is prevented. The black level depression means that the luminance of the light emitting element OLED becomes lower than the ideal characteristic, so that the light emission of the light emitting element OLED becomes dark.

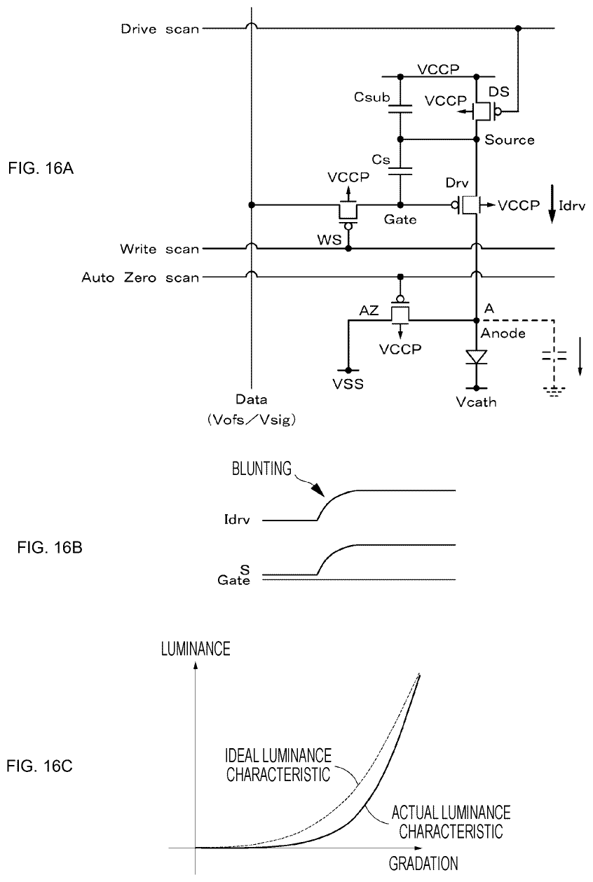

As illustrated in FIG. 16A, in a case where the pixel circuit operates in a source-grounded drive, as illustrated in FIG. 16B, a phenomenon that a current is blunted at the beginning of the flow of the drive current Idrv occurs. Thus, as illustrated in FIG. 16B, the amount of the drive current Idrv flowing through the light emitting element OLED at the beginning of the flow of the drive current Idrv decreases. Therefore, as illustrated in FIG. 16C, in the actual luminance characteristic of the light emitting element OLED, the luminance becomes lower than the ideal luminance characteristic, so that the black level depression occurs.

### [Configuration and Driving Method of Display Device]

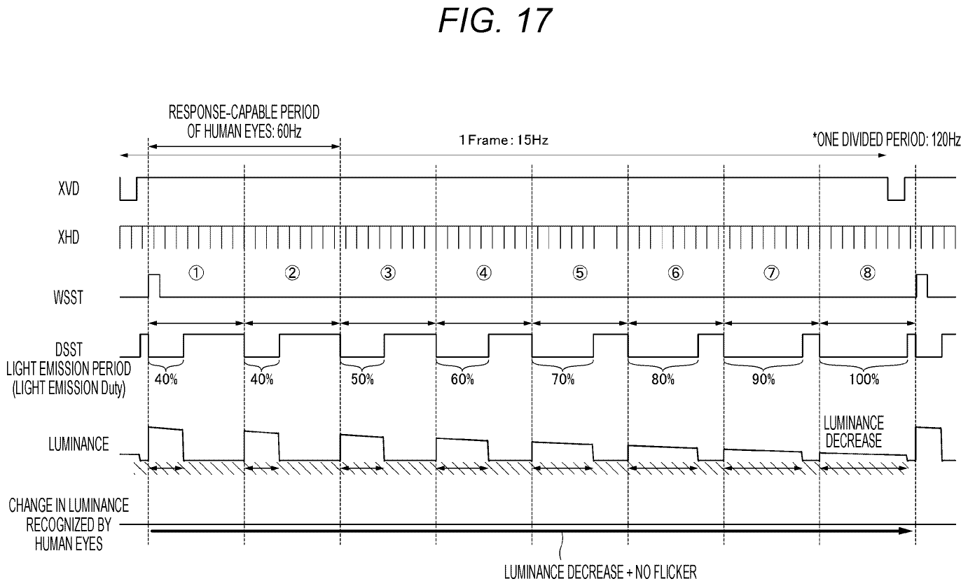

A configuration and a driving method of the display device 10 according to the third embodiment will be described. The configurations of the display system 100 and the display device 10 in the third embodiment are similar to those in the first embodiment. FIG. 17 is a diagram illustrating the vertical synchronization signal XVD, the horizontal synchronization signal XHD, the signal WSST, the signal DSST, and the change in the luminance of the pixel PIX for each frame of the video and the adjustment of the light emission period according to the third embodiment.

In the third embodiment, as illustrated in FIG. 17, in order to suppress the occurrence of flicker and prevent the occurrence of black level depression, the period of one frame (15 Hz) (one vertical scanning period) is divided into periods less than the response-capable period of human eyes, similarly to the first embodiment.

Then, the light emission period of the light emitting element OLED in the divided period corresponding to the period in which the blunting of the drive current Idrv occurs is lengthened. Therefore, it is possible to increase the amount of light emission in the first divided period and to prevent the occurrence of black level depression due to the blunting at the beginning of the flow of the drive current Idrv.

Thus, in the example of FIG. 17, specifically, as the divided period corresponding to the period in which the blunting of the drive current Idrv occurs, the light emission period of the first divided period is set to 40%, which is longer than that of the first embodiment.

After the drive current Idrv is stabilized, similarly to the first embodiment, the light emission duty is increased stepwise with the lapse of time, and the light emission period is adjusted to be lengthened stepwise. Thus, the light emission period of the second divided period is set to 40%. The light emission period of a third divided period is set to 50%. The light emission period of a fourth divided period is set to 60%. The light emission period of a fifth divided period is set to 70%. The light emission period of a sixth divided period is set to 80%. The light emission period of a seventh divided period is set to 90%. The light emission period of the eighth divided period is set to 100%.

For example, by changing the setting (register) of the timing controller 30 according to the blunting of the drive current Idrv specified in advance by measurement, calculation, or the like, the timing controller 30 generates the signal DSST for controlling the light emission period as described above, and supplies the signal DSST to the VLOGIC 42. Then, by supplying the signal DS from the V-DRV 15 to the pixel circuit, the light emission/non-light emission of the light emitting element OLED is controlled to adjust the light emission period of the pixel PIX.

In FIG. 17, the light emission period of the pixel PIX in the first divided period is set to 40%, but this is merely an example, and the duration of the light emission period of the pixel PIX in the divided period corresponding to the period in which the blunting of the drive current Idrv occurs may be appropriately set according to the blunting of the drive current Idrv.

Note that, in FIG. 17, the light emission period in the first divided period is lengthened, but in order to prevent the black level depression, it is necessary to lengthen the light emission period of the light emitting element OLED in the divided period corresponding to the period in which the blunting of the drive current Idrv occurs. Thus, for example, in a case where the period in which the peak of the drive current Idrv occurs is the first divided period and the second divided period, it is necessary to lengthen the light emission periods in the two divided periods.

As described above, in the third embodiment, the light emission period of each divided period is adjusted to be lengthened stepwise from the second divided period to the last divided period among the plurality of divided periods, and the light emission period in the first divided period among the plurality of divided periods is adjusted to be longer than or equal to the light emission period in the second divided period.

### Application Example

The display device 10 according to the above-described embodiment to which the present technology is applied may be provided in various electronic apparatuses. Examples of application of the electronic apparatuses include, for example, the following.

### Application Example 1

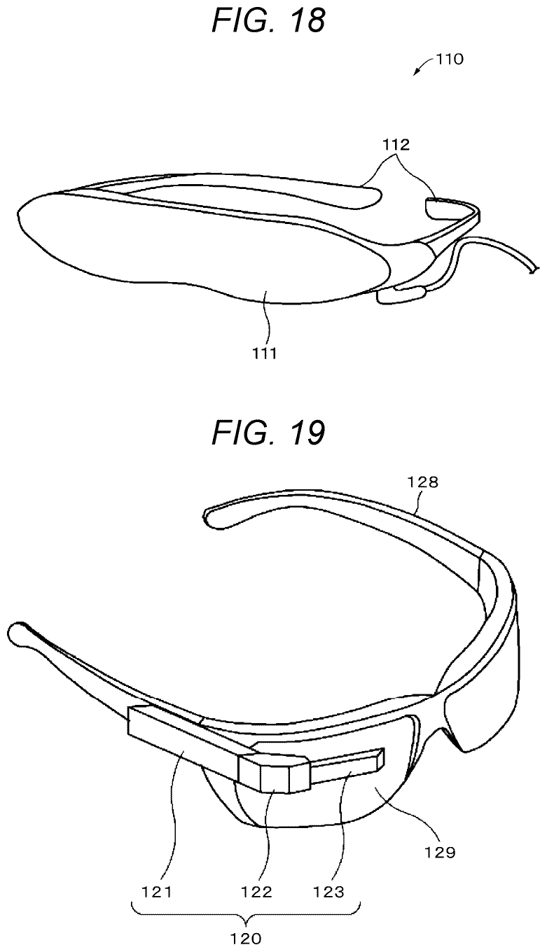

FIG. 18 illustrates an example of an appearance of a head-mounted display 110. The head-mounted display 110 includes, for example, ear hooking portions 112 to be worn on the head of the user on both sides of the glass-shaped display unit 111. The display unit 111 includes the display device 10 described above.

### Application Example 2

FIG. 19 illustrates an example of an appearance of a see-through head-mounted display 120. The see-through head-mounted display 120 includes a main body 121, an arm 122, and a lens barrel 123.

The main body 121 is connected to the arm 122 and glasses 128. Specifically, an end portion of the main body 121 in the long side direction is coupled to the arm 122, and one side of the side surface of the main body 121 is coupled to the glasses 128 via a connection member. Note that the main body 121 may be directly mounted on the head of the human body.

The main body 121 incorporates a control board for controlling the operation of the see-through head-mounted display 120 and a display unit. The arm 122 connects the main body 121 and the lens barrel 123 and supports the lens barrel 123. Specifically, the arm 122 is coupled to the end portion of the main body 121 and the end portion of the lens barrel 123, and fixes the lens barrel 123. Furthermore, the arm 122 incorporates a signal line SIG for communicating data related to an image provided from the main body 121 to the lens barrel 123.

The lens barrel 123 projects image light provided from the main body 121 via the arm 122 toward the eyes of the user wearing the see-through head-mounted display 120 through an eyepiece 129. In this see-through head-mounted display 120, the display unit of the main body 121 includes the display device 10 described above.

Note that the see-through head-mounted display 120 is a so-called light guide plate type head-mounted display, but is not limited thereto, and may be, for example, a so-called bird bus type head-mounted display. The bird bus type head-mounted display includes, for example, a beam splitter and a partially transparent mirror. The beam splitter outputs light encoded with the image information toward the mirror, and the mirror reflects the light toward the user's eyes. Both the beam splitter and the partially transparent mirror are partially transparent. Therefore, light from the surrounding environment reaches the eyes of the user.

### Application Example 3

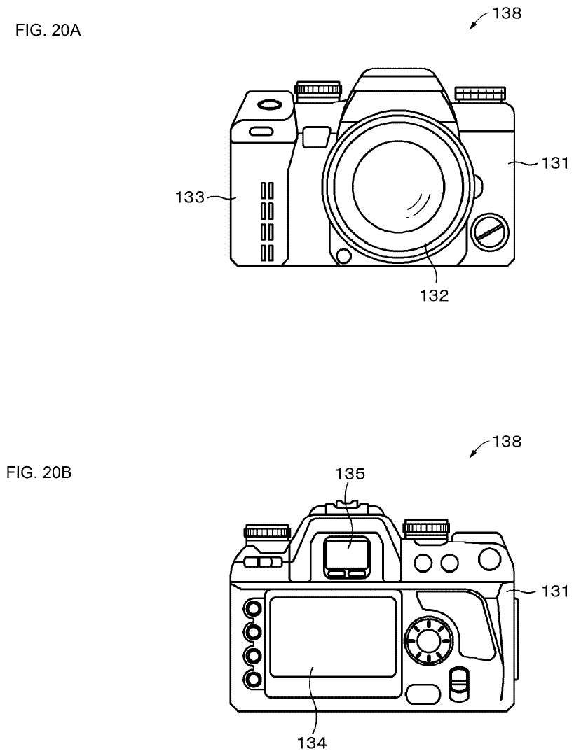

FIGS. 20A and 20B illustrate an example of an appearance of a digital still camera 138. The digital still camera 138 is of a lens interchangeable single-lens reflex type, and includes an interchangeable imaging lens unit (interchangeable lens) 132 substantially at the center of the front of the camera main body (camera body) 131, and a grip portion 133 to be held by a person who captures an image on the front left side.

A monitor 134 is provided at a position shifted to the left from the center of the back surface of the camera main body 131. An electronic view finder (eyepiece window) 135 is provided above the monitor 134. By looking into the electronic view finder 135, the person who captures an image can determine the composition by visually recognizing the optical image of the subject guided from the imaging lens unit 132. The electronic view finder 135 includes the display device 10 described above.

### Application Example 4

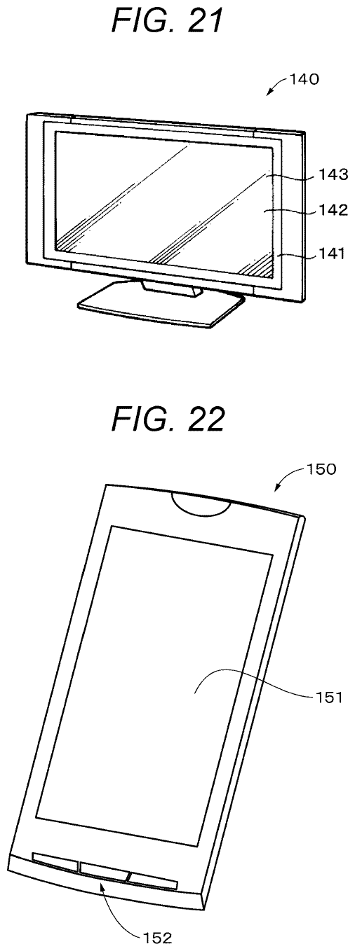

FIG. 21 illustrates an example of an appearance of a television apparatus 140. The television apparatus 140 includes, for example, a video display screen unit 141 including a front panel 142 and a filter glass 143, and the video display screen unit 141 includes the display device 10 described above.

### Application Example 5

FIG. 22 illustrates an example of an appearance of a smartphone 150. The smartphone 150 includes a display unit 151 for displaying various types of information, an operation unit 152 including a button for receiving an operation input by the user, and the like. The display unit 151 includes the display device 10 described above.

### Application Example 6

The above-described display device 10 and the like may be provided in various displays provided in vehicles.

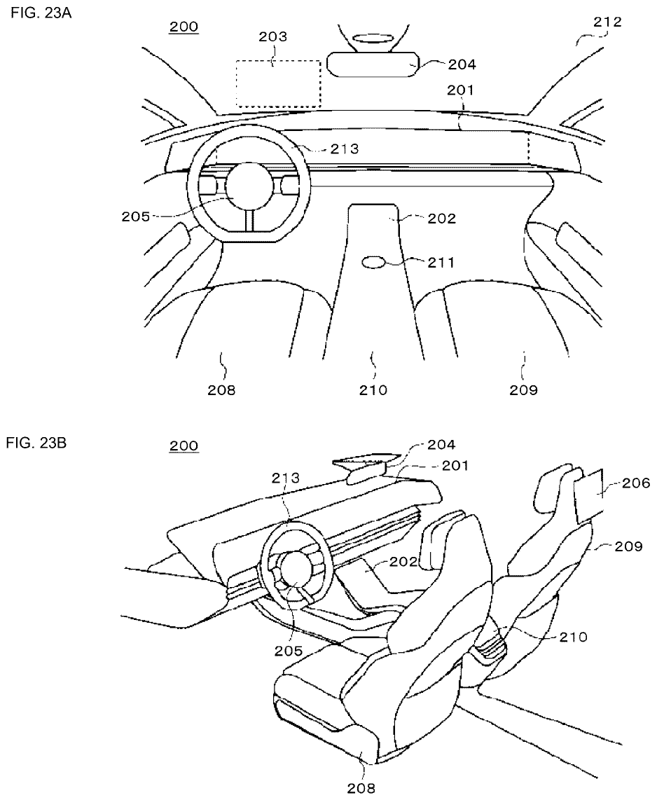

FIGS. 23A and 23B are diagrams illustrating an example of an internal configuration of a vehicle 200 provided with various displays. Specifically, FIG. 23A is a diagram illustrating the example of the internal state of the vehicle 200 from the rear to the front of the vehicle 200, and FIG. 23B is a diagram illustrating the example of the internal state of the vehicle 200 from the oblique rear to the oblique front of the vehicle 200.

The vehicle 200 includes a center display 201, a console display 202, a head-up display 203, a digital rear mirror 204, a steering wheel display 205, and a rear entertainment display 206. At least one of these displays includes the display device 10 described above. For example, all of these displays may include the display device 10 described above.

The center display 201 is disposed on a dashboard portion facing a driver's seat 208 and a passenger seat 209. FIGS. 23A and 23B illustrate an example of the center display 201 having a horizontally long shape extending from the driver's seat 208 side to the passenger seat 209 side, but the screen size and the arrangement place of the center display 201 are arbitrary. The center display 201 can display information detected by various sensors. As a specific example, the center display 201 can display a captured image captured by the image sensor, a distance image to an obstacle in front of or on a side of the vehicle 200 measured by the TOF sensor, a passenger's body temperature detected by the infrared sensor, and the like. The center display 201 can be used to display, for example, at least one of safety-related information, operation-related information, a life log, health-related information, authentication/identification-related information, or entertainment-related information.

The safety-related information is information about doze sensing, looking-away sensing, sensing of mischief of a child riding together, presence or absence of wearing of a seat belt, sensing of leaving of an occupant, and the like, and is information sensed by a sensor disposed in an overlapping manner on the back surface side of the center display 201, for example. The operation-related information detects a gesture related to the operation of an occupant using the sensor. The sensed gestures may include operation of various equipment in the vehicle 200. For example, operations of air conditioning equipment, a navigation apparatus, an AV apparatus, a lighting apparatus, and the like are detected. The lifelog includes a lifelog of all the occupants. For example, the lifelog includes an action record of each occupant in the vehicle. By acquiring and storing the lifelog, it is possible to confirm the state of an occupant at the time of an accident. The health-related information detects the body temperature of an occupant using a sensor such as a temperature sensor, and estimates the health condition of the occupant on the basis of the detected body temperature. Alternatively, the face of the occupant may be imaged using an image sensor, and the health condition of the occupant may be estimated from the imaged facial expression. Moreover, a conversation may be made with the occupant in an automatic voice, and the health condition of the occupant may be estimated on the basis of the answer content of the occupant. The authentication/identification-related information includes a keyless entry function of performing face authentication using a sensor, a function of performing automatic adjustment of a sheet height and a position in face identification, and the like. The entertainment-related information includes a function of detecting operation information of the AV apparatus by an occupant using the sensor, a function of recognizing the face of an occupant by the sensor and providing content suitable for the occupant by the AV apparatus, and the like.

The console display 202 can be used to display the lifelog information, for example. The console display 202 is disposed near a shift lever 211 of a center console 210 between the driver's seat 208 and the passenger seat 209. The console display 202 can also display information detected by various sensors. Furthermore, the console display 202 may display an image of the periphery of the vehicle captured by the image sensor, or may display a distance image to an obstacle in the periphery of the vehicle.

The head-up display 203 is virtually displayed behind the windshield 212 in front of the driver's seat 208. The head-up display 203 can be used to display, for example, at least one of the safety-related information, the operation-related information, the life log, the health-related information, the authentication/identification-related information, or the entertainment-related information. Since the head-up display 203 is virtually disposed in front of the driver's seat 208 in many cases, it is suitable for displaying information directly related to the operation of the vehicle 200 such as the speed of the vehicle 200 and the remaining amount of fuel (battery).

The digital rear mirror 204 can not only display the rear of the vehicle 200 but also display the state of the occupants in the rear seat, and thus can be used to display the lifelog information, for example, by disposing the sensor in an overlapping manner on the back surface side of the digital rear mirror 204.

The steering wheel display 205 is disposed near the center of the steering wheel 213 of the vehicle 200. The steering wheel display 205 can be used to display, for example, at least one of the safety-related information, the operation-related information, the life log, the health-related information, the authentication/identification-related information, or the entertainment-related information. In particular, since the steering wheel display 205 is close to the driver's hand, it is suitable for displaying lifelog information such as the body temperature of the driver, or for displaying information regarding the operation of an AV device, air conditioning equipment, or the like.

The rear entertainment display 206 is attached to the back side of the driver's seat 208 and the passenger seat 209, and is for viewing by the occupants in the rear seat. The rear entertainment display 206 can be used to display, for example, at least one of the safety-related information, the operation-related information, the life log, the health-related information, the authentication/identification-related information, or the entertainment-related information. In particular, because the rear entertainment display 206 is in front of the occupant in the rear seat, information related to the occupant in the rear seat is displayed. For example, information regarding the operation of the AV device or the air conditioning equipment may be displayed, or a result of measuring the body temperature or the like of the occupant in the rear seat by the temperature sensor may be displayed.

A sensor may be disposed in an overlapping manner on the back surface side of the display device 10, and a distance to an object existing in the surroundings may be measured. Optical distance measurement methods are roughly classified into a passive type and an active type. The passive type measures a distance by receiving light from an object without projecting light from a sensor to the object. The passive type includes a lens focus method, a stereo method, a monocular vision method, and the like. In the active type, light is projected onto an object, and reflected light from the object is received by a sensor to measure a distance. Examples of the active type include an optical radar method, an active stereo method, an illuminance difference stereo method, a moire topography method, and an interference method. The display devices 10 described above can be used also in distance measurement by any of these methods. By using the sensor disposed to overlap the back surface side of the display device 10 described above, the above-described passive or active distance measurement can be performed.

### Modification

In the above-described embodiment, the pixel array unit 11 has been described as having a rectangular shape. However, the shape of the pixel array unit 11 is not limited to a rectangular shape, and may be a square shape, a circular shape, an elliptical shape, or a polygonal shape other than a rectangular shape.

In the first to third embodiments, one frame is divided into eight divided periods, but the number of divided periods of one frame is not limited to eight, and may be eight or more or may be less than eight.

For example, the pixel PIX is not limited to that of the configuration example (including the modification) described above, and can be appropriately changed, for example, such that a P-channel transistor is changed to an N-channel transistor.

The type, number, and connection of the transistor, the capacitor, and the light emitting element OLED can be appropriately changed. Various video signals and control signals are only required to be generated accordingly and supplied to the pixel PIX.

The present technology is not limited to the pixel circuit having the 4-Transistor (Tr) 2-Capacitor (C) configuration illustrated in FIG. 2, and can be applied to any configuration as long as the display device can adjust the light emission time by controlling the light emission/non-light emission of the pixel PIX.

For example, configurations, methods, processes, shapes, materials, numerical values, and the like of the above-described embodiments can be combined or exchanged with each other without departing from the gist of the present technology. Furthermore, one may be divided into two or more, and a part thereof may be omitted.

Note that effects described in the present specification are merely examples and are not limited, and other effects may be provided.

The present technology can also have the following configurations.

(1)

A display device including:
a pixel region in which a plurality of pixels is disposed; and
a light emission control unit that controls light emission/non-light emission of the pixel, in which
a length of a light emission period of the pixel in a plurality of divided periods into which one frame of a video to be displayed is divided is adjusted by controlling the light emission and the non-light emission of the pixel.
   (2)

The display device according to (1), in which the light emission period of each divided period is adjusted to be lengthened stepwise from a first divided period to a last divided period among the plurality of divided periods.

(3)

The display device according to (1) or (2), in which the divided period is shorter than a response-capable period of human eyes.

(4)

The display device according to any one of (1) to (3), in which the length of the light emission period of the pixel in the divided period is adjusted in a case where a frame rate of the video is low.

(5)

The display device according to (4), in which the case where the frame rate of the video is low is a case where the frame rate is 30 Hz or less.

(6)

The display device according to any one of (1) to (5), in which the light emission period in a first divided period among the plurality of divided periods is shortened.

(7)

The display device according to any one of (1) to (6), in which the light emission period in a first divided period among the plurality of divided periods is lengthened.

(8)

The display device according to any one of (1) to (7), in which the light emission period of the pixel in a divided period, which corresponds to a range of a peak of a drive current input to the pixel, among the plurality of divided periods is shortened.

(9)

The display device according to any one of (1) to (8), in which the light emission period of the pixel in a divided period, which corresponds to a range of blunting of a drive current input to the pixel, among the plurality of divided periods is lengthened.

(10)

The display device according to any one of (1) to (9), in which the light emission period of each divided period is adjusted to be lengthened stepwise from a first divided period to a last divided period among the plurality of divided periods, and an amount of change in the length of the light emission period from the first divided period to the second divided period is adjusted to be larger than an amount of change in the length of the light emission period from the second divided period to a third divided period.

(11)

The display device according to any one of (1) to (10), in which the light emission period in each divided period is adjusted to be lengthened stepwise from a second divided period to a last divided period among the plurality of divided periods, and the light emission period in a first divided period among the plurality of divided periods is adjusted to be longer than or equal to the light emission period in the second divided period.

(12)

The display device according to any one of (1) to (11), in which the length of the light emission period of the pixel is adjusted by switching between the light emission and the non-light emission of the pixel.

(13)

A method of driving a display device which includes
a pixel region in which a plurality of pixels is disposed, and
a light emission control unit that controls light emission/non-light emission of the pixel,
the method including:
adjusting a length of a light emission period of the pixel in a plurality of divided periods into which one frame of a video to be displayed is divided, by controlling the light emission and the non-light emission of the pixel.
   (14)

An electronic apparatus including the display device according to any one of (1) to (12).

### REFERENCE SIGNS LIST

10 Display device
11 Pixel array unit
13 Drive scanning unit

1. A display device comprising:
a pixel region in which a plurality of pixels is disposed; and
a light emission control unit that controls light emission and non-light emission of the pixel, wherein
a length of a light emission period of the pixel in a plurality of divided periods into which one frame of a video to be displayed is divided is adjusted by controlling the light emission and the non-light emission of the pixel so as to shorten the light emission period of the pixel in the divided period, which corresponds to a range of a peak of an input drive current, among the plurality of divided periods or lengthen the light emission period of the pixel in the divided period, which corresponds to a range of blunting of an input drive current, among the plurality of divided periods.

2. The display device according to claim 1, wherein
the light emission period of each divided period is adjusted to be lengthened stepwise from a first divided period to a last divided period among the plurality of divided periods.

3. The display device according to claim 1, wherein
the divided period is shorter than a response-capable period of human eyes.

4. The display device according to claim 1, wherein
the length of the light emission period of the pixel in the divided period is adjusted in a case where a frame rate of the video is low.

5. The display device according to claim 4, wherein
the case where the frame rate of the video is low is a case where the frame rate is 30 Hz or less.

6. The display device according to claim 1, wherein the light emission period in a first divided period among the plurality of divided periods is lengthened.

7. The display device according to claim 1, wherein the light emission period in a first divided period among the plurality of divided periods is shortened.

8. The display device according to claim 1, wherein
the light emission period of the pixel in a divided period, which corresponds to a range of a peak of a drive current input to the pixel, among the plurality of divided periods is shortened.

9. The display device according to claim 1, wherein
the light emission period of the pixel in a divided period, which corresponds to a range of blunting of a drive current input to the pixel, among the plurality of divided periods is lengthened.

10. The display device according to claim 1, wherein
the light emission period of each divided period is adjusted to be lengthened stepwise from a first divided period to a last divided period among the plurality of divided periods, and an amount of change in the length of the light emission period from the first divided period to the second divided period is adjusted to be larger than an amount of change in the length of the light emission period from the second divided period to a third divided period.

11. The display device according to claim 1, wherein
the light emission period in each divided period is adjusted to be lengthened stepwise from a second divided period to a last divided period among the plurality of divided periods, and the light emission period in a first divided period among the plurality of divided periods is adjusted to be longer than or equal to the light emission period in the second divided period.

12. The display device according to claim 1, wherein
the length of the light emission period of the pixel is adjusted by switching between the light emission and the non-light emission of the pixel.

13. A method of driving a display device which includes
a pixel region in which a plurality of pixels is disposed, and
a light emission control unit that controls light emission and non-light emission of the pixel,
the method comprising:
adjusting a length of a light emission period of the pixel in a plurality of divided periods into which one frame of a video to be displayed is divided, by controlling the light emission and the non-light emission of the pixel so as to shorten the light emission period of the pixel in the divided period, which corresponds to a range of a peak of an input drive current, among the plurality of divided periods or lengthen the light emission period of the pixel in the divided period, which corresponds to a range of blunting of an input drive current, among the plurality of divided periods.

14. An electronic apparatus comprising the display device according to claim 1.
